(19) United States
(12) Patent Application Publication
(10) Pub. No.: US 2020/0006523 A1
(43) Pub. Date: Jan. 2, 2020

(54) CHANNEL LAYER FOR III-V METAL-OXIDE-SEMICONDUCTOR FIELD EFFECT TRANSISTORS (MOSFETS)

(71) Applicant: Intel Corporation, Santa Clara, CA (US)

(72) Inventors: Matthew METZ, Portland, OR (US); Willy RACHMADY, Beaverton, OR (US); Sean MA, Portland, OR (US); Jessica TORRES, Portland, OR (US); Nicholas MINUTILLO, Beaverton, OR (US); Cheng-Ying HUANG, Hillsboro, OR (US); Anand MURTHY, Portland, OR (US); Harold KENNEL, Portland, OR (US); Gilbert DEWEY, Beaverton, OR (US); Jack KAVALIEROS, Portland, OR (US); Tahir GHANI, Portland, OR (US)

(21) Appl. No.: 16/024,699

(22) Filed: Jun. 29, 2018

(51) Int. Cl. H01L 29/66; H01L 21/02

(52) U.S. Cl. CPC H01L 29/66522; H01L 21/84; H01L 21/02614; H01L 21/02546

(57) ABSTRACT

Embodiments herein describe techniques, systems, and method for a semiconductor device. Embodiments herein may present a semiconductor device including a substrate with a surface that is substantially flat. A channel area including an III-V compound may be above the substrate, where the channel area is an epitaxial layer directly in contact with the surface of the substrate. A gate dielectric layer is adjacent to the channel area and in direct contact with the channel area, while a gate electrode is adjacent to the gate dielectric layer. Other embodiments may be described and/or claimed.

### FIELD

Embodiments of the present disclosure generally relate to the field of integrated circuits, and more particularly, to III-V metal-oxide-semiconductor field effect transistors (MOSFETs).

### BACKGROUND

The background description provided herein is for the purpose of generally presenting the context of the disclosure. Unless otherwise indicated herein, the materials described in this section are not prior art to the claims in this application and are not admitted to be prior art by inclusion in this section.

Traditional integrated circuits, e.g., metal-oxide-semiconductor field effect transistors (MOSFETs), may be based on silicon. On the other hand, compounds of group III-V elements may have superior semiconductor properties than silicon, including higher electron mobility and saturation velocity, leading to better performance for III-V MOSFETs, or simply III-V transistors. However, the fabrication process for III-V MOSFETs may be complicated and expensive with high defect product rates.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example and not by way of limitation in the figures of the accompanying drawings.

FIGS. 1(a)-1(b) schematically illustrate an example III-V metal-oxide-semiconductor field effect transistor (MOSFET) including an epitaxial layer with an III-V compound as a channel area directly in contact with a surface of a substrate, in accordance with some embodiments.

FIG. 2 schematically illustrates an example process for forming an III-V MOSFET including an epitaxial layer with an III-V compound as a channel area directly in contact with a surface of a substrate, in accordance with some embodiments.

FIGS. 3(a)-3(h) schematically illustrate another example process with more details for forming an III-V MOSFET including an epitaxial layer with an III-V compound as a channel area directly in contact with a surface of a substrate, in accordance with some embodiments.

FIG. 4 schematically illustrates a diagram of a semiconductor device including an III-V MOSFET having an epitaxial layer with an III-V compound as a channel area directly in contact with a surface of a substrate formed in back-end-of-line (BEOL) on a substrate, in accordance with some embodiments.

FIG. 5 schematically illustrates an interposer implementing one or more embodiments of the disclosure, in accordance with some embodiments.

FIG. 6 schematically illustrates a computing device built in accordance with an embodiment of the disclosure, in accordance with some embodiments.

### DETAILED DESCRIPTION

Compounds of group III-V elements such as gallium arsenide (GaAs), indium antimonide (InSb), indium phosphide (InP), and indium gallium arsenide (InGaAs) have superior semiconductor properties than silicon, including higher electron mobility and saturation velocity. As a result, III-V metal-oxide-semiconductor field effect transistors (MOSFETs) may have better performance than silicon transistors as well. An III-V MOSFET, or simply referred to as an III-V transistor, may include a source area and a drain area adjacent to a channel area. For the description below, a source area and a drain area may be used interchangeably.

An III-V transistor may include an epitaxial layer as a channel area. However, growing a high quality epitaxial layer on a substrate, e.g., a silicon substrate, may be a difficult task. Conventionally, an epitaxial layer for a channel area may be coupled to other epitaxial layers via complex buffer layers, which may be time consuming and expensive to fabricate. Embodiments herein may present an III-V transistor having an epitaxial layer with an III-V compound as a channel area directly in contact with a surface of the substrate. The substrate may have a substantially flat surface, and the epitaxial layer of the channel area is in direct contact with the surface of the substrate without a buffer layer or another epitaxial layer in between. The epitaxial layer of the channel area may be formed by annealing a patterned precursor area with a coreactant. The precursor layer includes a precursor material with a group III element, while the coreactant includes a group V element, so that an III-V compound may be formed by annealing the channel area. As such, the III-V transistor may be less costly to fabricate with improved performance and reduced defect product rates.

Embodiments herein may present a semiconductor device. The semiconductor device may include a substrate with a surface that is substantially flat. A channel area including an III-V compound may be above the substrate, where the channel area is an epitaxial layer directly in contact with the surface of the substrate. A gate dielectric layer is adjacent to the channel area and in direct contact with the channel area, while a gate electrode is adjacent to the gate dielectric layer.

Embodiments herein may present a method for forming a semiconductor device. The method may include forming a precursor layer directly above and in contact with a surface of a substrate. The precursor layer includes a precursor material with a group III element, and the surface of the substrate is substantially flat. The method may further include forming a capping layer above the precursor layer, and patterning the capping layer and the precursor layer to form a patterned precursor area covered by the capping layer. The patterned precursor area is with an aspect ratio (x, y, z). In addition, the method may include annealing the patterned precursor area with a coreactant, where the coreactant includes a group V element. As a result, the patterned precursor area is transformed to a patterned epitaxial layer directly in contact with the surface of the substrate. The patterned epitaxial layer may be a channel area including an III-V compound formed by the precursor material and the coreactant. Furthermore, the method may include removing the capping layer, forming a gate dielectric layer adjacent to the channel area and in direct contact with the channel area, and forming a gate electrode adjacent to the gate dielectric layer.

Embodiments herein may present a computing device. The computing device may include a processor and a memory device coupled to the processor. The memory device or the processor includes a transistor. The transistor may include a substrate with a surface that is substantially flat. A channel area including an III-V compound may be above the substrate, where the channel area is an epitaxial layer directly in contact with the surface of the substrate. A gate dielectric layer is above the channel area and in direct contact with the channel area, while a gate electrode is above the gate dielectric layer.

In the following description, various aspects of the illustrative implementations will be described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials and configurations are set forth in order to provide a thorough understanding of the illustrative implementations. However, it will be apparent to one skilled in the art that the present disclosure may be practiced without the specific details. In other instances, well-known features are omitted or simplified in order not to obscure the illustrative implementations.

Various operations will be described as multiple discrete operations, in turn, in a manner that is most helpful in understanding the present disclosure. However, the order of description should not be construed to imply that these operations are necessarily order dependent. In particular, these operations may not be performed in the order of presentation.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The terms “over,” “under,” “between,” “above,” and “on” as used herein may refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

In various embodiments, the phrase “a first feature formed, deposited, or otherwise disposed on a second feature” may mean that the first feature is formed, deposited, or disposed over the second feature, and at least a part of the first feature may be in direct contact (e.g., direct physical and/or electrical contact) or indirect contact (e.g., having one or more other features between the first feature and the second feature) with at least a part of the second feature.

Where the disclosure recites “a” or “a first” element or the equivalent thereof, such disclosure includes one or more such elements, neither requiring nor excluding two or more such elements. Further, ordinal indicators (e.g., first, second, or third) for identified elements are used to distinguish between the elements, and do not indicate or imply a required or limited number of such elements, nor do they indicate a particular position or order of such elements unless otherwise specifically stated.

As used herein, the term “circuitry” may refer to, be part of, or include an Application Specific Integrated Circuit (ASIC), an electronic circuit, a processor (shared, dedicated, or group), and/or memory (shared, dedicated, or group) that execute one or more software or firmware programs, a combinational logic circuit, and/or other suitable hardware components that provide the described functionality. As used herein, “computer-implemented method” may refer to any method executed by one or more processors, a computer system having one or more processors, a mobile device such as a smartphone (which may include one or more processors), a tablet, a laptop computer, a set-top box, a gaming console, and so forth.

Implementations of the disclosure may be formed or carried out on a substrate, such as a semiconductor substrate. In one implementation, the semiconductor substrate may be a crystalline substrate formed using a bulk silicon or a silicon-on-insulator substructure. In other implementations, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-V or group IV materials. Although a few examples of materials from which the substrate may be formed are described here, any material that may serve as a foundation upon which a semiconductor device may be built falls within the spirit and scope of the present disclosure.

A plurality of transistors, such as metal-oxide-semiconductor field-effect transistors (MOSFET or simply MOS transistors), may be fabricated on the substrate. In various implementations of the disclosure, the MOS transistors may be planar transistors, nonplanar transistors, or a combination of both. Nonplanar transistors include FinFET transistors such as double-gate transistors and tri-gate transistors, and wrap-around or all-around gate transistors such as nanoribbon and nanowire transistors. Although the implementations described herein may illustrate only planar transistors, it should be noted that the disclosure may also be carried out using nonplanar transistors.

Each MOS transistor includes a gate stack formed of at least two layers, a gate dielectric layer and a gate electrode layer. The gate dielectric layer may include one layer or a stack of layers. The one or more layers may include silicon oxide, silicon dioxide (SiO₂) and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used.

The gate electrode layer is formed on the gate dielectric layer and may consist of at least one P-type work function metal or N-type work function metal, depending on whether the transistor is to be a PMOS or an NMOS transistor. In some implementations, the gate electrode layer may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, and conductive metal oxides, e.g., ruthenium oxide. A P-type metal layer will enable the formation of a PMOS gate electrode with a work function that is between about 4.9 eV and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, and aluminum carbide. An N-type metal layer will enable the formation of an NMOS gate electrode with a work function that is between about 3.9 eV and about 4.2 eV.

In some implementations, when viewed as a cross-section of the transistor along the source-channel-drain direction, the gate electrode may consist of a “U”-shaped structure that includes a bottom portion substantially parallel to the surface of the substrate and two sidewall portions that are substantially perpendicular to the top surface of the substrate. In another implementation, at least one of the metal layers that form the gate electrode may simply be a planar layer that is substantially parallel to the top surface of the substrate and does not include sidewall portions substantially perpendicular to the top surface of the substrate. In further implementations of the disclosure, the gate electrode may consist of a combination of U-shaped structures and planar, non-U-shaped structures. For example, the gate electrode may consist of one or more U-shaped metal layers formed atop one or more planar, non-U-shaped layers.

In some implementations of the disclosure, a pair of sidewall spacers may be formed on opposing sides of the gate stack that bracket the gate stack. The sidewall spacers may be formed from a material such as silicon nitride, silicon oxide, silicon carbide, silicon nitride doped with carbon, and silicon oxynitride. Processes for forming sidewall spacers are well known in the art and generally include deposition and etching process operations. In an alternate implementation, a plurality of spacer pairs may be used, for instance, two pairs, three pairs, or four pairs of sidewall spacers may be formed on opposing sides of the gate stack.

As is well known in the art, source and drain regions are formed within the substrate adjacent to the gate stack of each MOS transistor. The source and drain regions are generally formed using either an implantation/diffusion process or an etching/deposition process. In the former process, dopants such as boron, aluminum, antimony, phosphorous, or arsenic may be ion-implanted into the substrate to form the source and drain regions. An annealing process that activates the dopants and causes them to diffuse further into the substrate typically follows the ion implantation process. In the latter process, the substrate may first be etched to form recesses at the locations of the source and drain regions. An epitaxial deposition process may then be carried out to fill the recesses with material that is used to fabricate the source and drain regions. In some implementations, the source and drain regions may be fabricated using a silicon alloy such as silicon germanium or silicon carbide. In some implementations the epitaxially deposited silicon alloy may be doped in situ with dopants such as boron, arsenic, or phosphorous. In further embodiments, the source and drain regions may be formed using one or more alternate semiconductor materials such as germanium or a group III-V material or alloy. And in further embodiments, one or more layers of metal and/or metal alloys may be used to form the source and drain regions.

One or more interlayer dielectrics (ILD) are deposited over the MOS transistors. The ILD layers may be formed using dielectric materials known for their applicability in integrated circuit structures, such as low-k dielectric materials. Examples of dielectric materials that may be used include, but are not limited to, silicon dioxide (SiO₂), carbon doped oxide (CDO), silicon nitride, organic polymers such as perfluorocyclobutane or polytetrafluoroethylene, fluorosilicate glass (FSG), and organosilicates such as silsesquioxane, siloxane, or organosilicate glass. The ILD layers may include pores or air gaps to further reduce their dielectric constant.

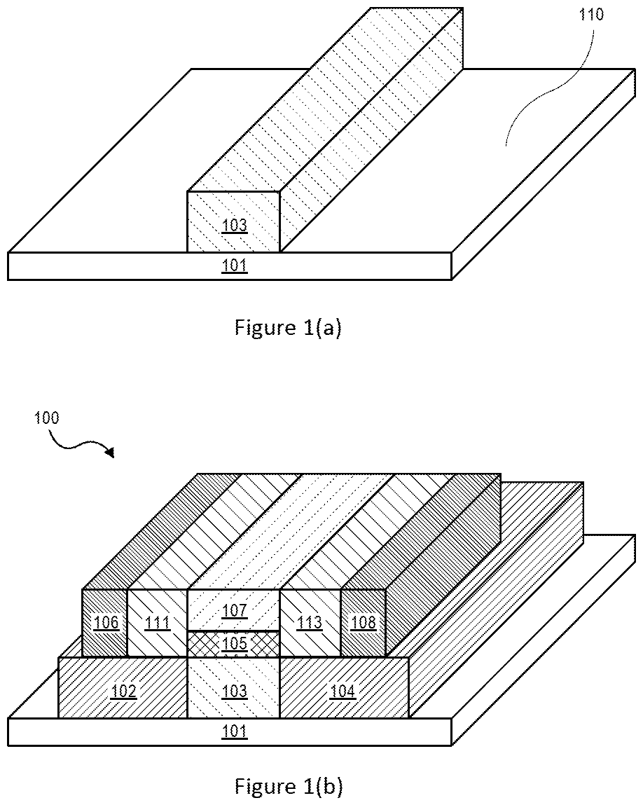

FIGS. 1(a)-1(b) schematically illustrate an example III-V MOSFET 100 including an epitaxial layer with an III-V compound as a channel area 103 directly in contact with a surface 110 of a substrate 101, in accordance with some embodiments. For clarity, features of the III-V MOSFET 100, the channel area 103, and the substrate 101, may be described below as examples for understanding an III-V MOSFET, a channel area, and a substrate. Further, it is to be understood that one or more of the components of an III-V MOSFET, a channel area, and a substrate may include additional and/or varying features from the description below, and may include any device that one having ordinary skill in the art would consider and/or refer to as an III-V MOSFET, a channel area, and a substrate.

In embodiments, the III-V MOSFET 100 may be an NMOS transistor, or a PMOS transistor. The III-V MOSFET 100 includes the substrate 101 with the surface 110, which is substantially flat. The channel area 103 is above the surface 110 of the substrate 101. The channel area 103 is an epitaxial layer including an III-V compound and directly in contact with the surface 110 of the substrate 101. A gate dielectric layer 105 is above the channel area 103 and in direct contact with the channel area 103. A gate electrode 107 is above the gate dielectric layer 105. A source area 102 and a drain area 104 are above the substrate 101 and adjacent to the channel area 103. A source electrode 106 is in contact with the source area 102, and a drain electrode 108 is in contact with the drain area 104. A spacer 111 may be along a side wall of the gate electrode 107 to separate the gate electrode 107 and the source electrode 106, while a spacer 113 may be along a side wall of the gate electrode 107 to separate the gate electrode 107 and drain electrode 108.

In embodiments, the channel area 103 may be a FinFET channel, a nanowire channel, a vertical FET channel, a nanotube channel, or a nanoribbon channel. The channel area 103 includes an III-V compound, which may be a binary III-V compound, a ternary III-V compound, or a quaternary III-V compound. In detail, the III-V compound in the channel area 103 may include aluminum (Al), gallium (Ga), indium (In), nitrogen (N), phosphorus (P), arsenic (As), antimony (Sb), AlAs, GaAs, InₓGa₁₋ₓAs, InₓAl₁₋ₓAs InₓGa₁₋ₓP, InₓAl₁₋ₓP, GaAsₓSb₁₋ₓ, AlₓGa₁₋ₓAs_{y}P_{1-y} where x and y are between 0 and 1, InSb, InAs, AlP, GaP, or InP. The channel area 103 is in direct contact with the surface 110 of the substrate 101 without a buffer layer or another epitaxial layer in between. In embodiments, the channel area 103 may be a rectangular cuboid with an aspect ratio (x, y, z). For example, the channel area 103 may be a rectangular cuboid with a (x, y) aspect ratio as 2:1. The channel area 103 may be of other shape, such as a triangular shape, a square shape, or a polygon shape.

In embodiments, gate dielectric layer 105 may include a high-k dielectric material. For example, gate dielectric layer 105 may include a material with a dielectric constant of at least about 10. In detail, gate dielectric layer 105 may include Al₂O₃, although other materials such as La₂O₃, HfO₂, ZrO₂, or ternary complexes such as LaAlₓO_{y}, HfₓZr_{y}O_{z} may be used in other embodiments.

In embodiments, the source electrode 106, the drain electrode 108, or the gate electrode 107 may be formed as a single layer or a stacked layer using one or more conductive films including a conductive material. For example, the source electrode 106, the drain electrode 108, or the gate electrode 107 may include a metallic material, a conductive polymer, a polysilicon, a titanium silicide, a phosphorus (n+) doped Si, a boron doped SiGe, or an alloy of a semiconductor material and a metal. For example the source electrode 106, the drain electrode 108, or the gate electrode 107 may include gold (Au), platinum (Pt), ruthenium (Ru), iridium (Ir), titanium (Ti), aluminum (Al), molybdenum (Mo), copper (Cu), tantalum (Ta), tungsten (W), nickel (Ni), chromium (Cr), hafnium (Hf), indium (In), or an alloy of Ti, Mo, Au, Pt, Al, Ni, Cu, Cr, TiAlN, HfAlN, or InAlO. The source electrode 106, the drain electrode 108, or the gate electrode 107 may include tantalum nitride (TaN), titanium nitride (TiN), iridium-tantalum alloy (Ir—Ta), indium-tin oxide (ITO), the like, and/or a combination thereof.

In embodiments, the substrate 101 may be a silicon substrate, a glass substrate, such as soda lime glass or borosilicate glass, a metal substrate, a plastic substrate, a polyimide substrate, or other suitable substrate. The substrate 101 may include silicon, sapphire, SiC, GaN, AlN, SiO2, or Cu. The substrate includes a high-resistivity p-type or n-type vicinal silicon material, germanium, germanium on silicon, gallium arsenide (GaAs), or a silicon-on-insulator substrate. For example, the substrate 101 may be a silicon substrate with a (111), (100), or (110) crystal plane as a principal plane.

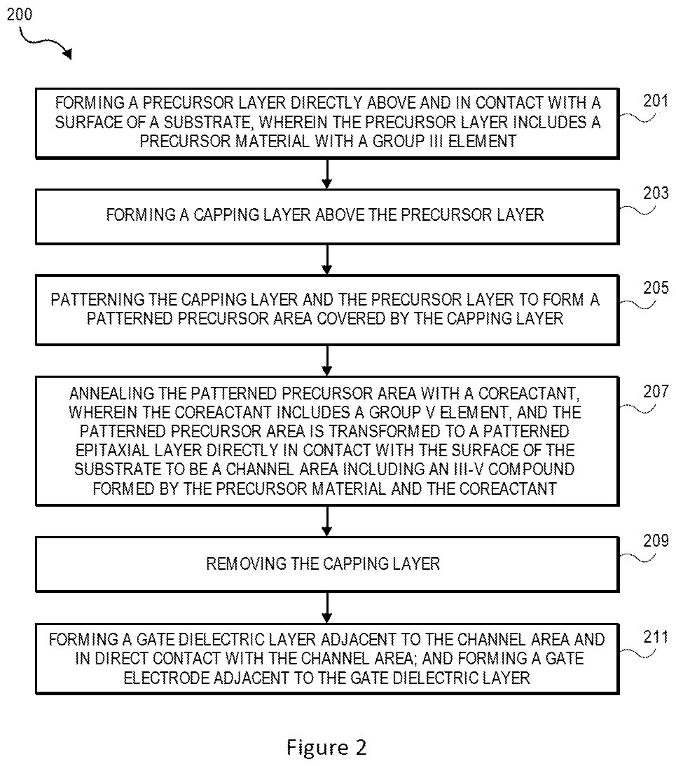

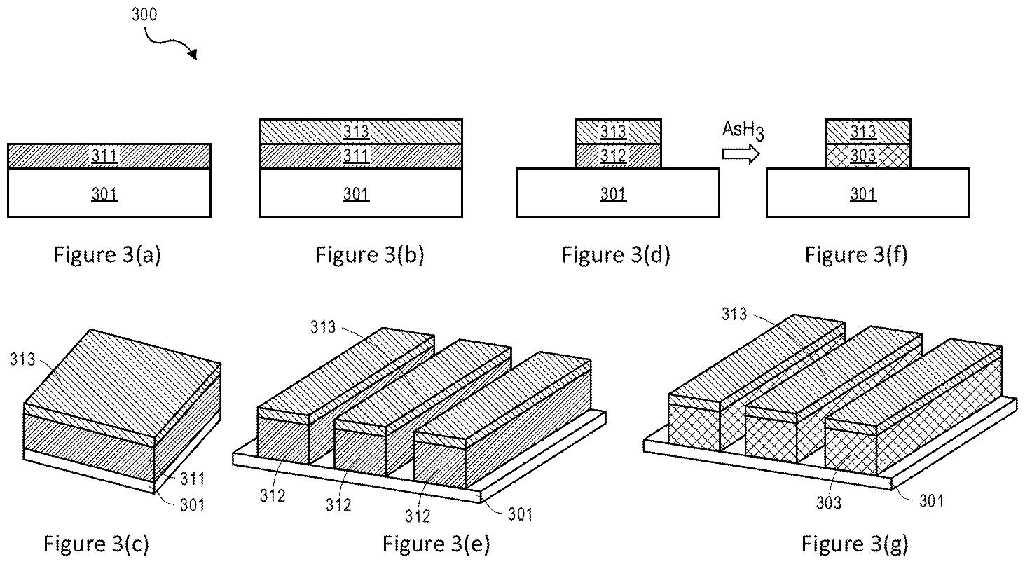

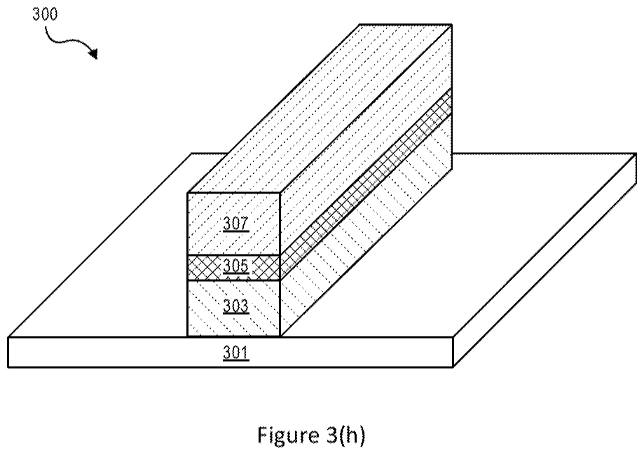

FIG. 2 schematically illustrates an example process 200 for forming an III-V MOSFET including an epitaxial layer with an III-V compound as a channel area directly in contact with a surface of a substrate, in accordance with some embodiments. FIGS. 3(a)-3(h) schematically illustrate another example process 300 with more details for forming an III-V MOSFET including an epitaxial layer with an III-V compound as a channel area directly in contact with a surface of a substrate, in accordance with some embodiments. The details shown in FIGS. 3(a)-3(h) for the process 300 may be illustrative for the process 200. In embodiments, the process 200 or the process 300 may be used to form the III-V MOSFET 100 as shown in FIG. 1.

At block 201, the process 200 may include forming a precursor layer directly above and in contact with a surface of a substrate, wherein the precursor layer includes a precursor material with a group III element. For example, as shown in FIG. 3(a), the process 300 may include forming a precursor layer 311 directly above and in contact with a surface of a substrate 301. The precursor layer 311 may include a group III element, e.g., Ga. The surface of the substrate 301 may be substantially flat.

At block 203, the process 200 may include forming a capping layer above the precursor layer. For example, as shown in FIG. 3(b), the process 200 may include forming a capping layer 313 above the precursor layer 311. FIG. 3(c) shows in three-dimensional view that the capping layer 313 above the precursor layer 311, which is further above the substrate 301. In embodiments, the capping layer 313 may include silicon oxide, silicon nitride, silicon oxynitride, silicon carbide, or a low-dielectric-constant (low-K) dielectric material. The capping layer 313 may have a thickness in a range from about 2 nm to about 500 nm.

At block 205, the process 200 may include patterning the capping layer and the precursor layer to form a patterned precursor area covered by the capping layer, where the patterned precursor area is with an aspect ratio (x, y, z). For example, as shown in FIG. 3(d), the process 200 may pattern the capping layer 313 and the precursor layer 311 to form a patterned precursor area 312 covered by the capping layer 313. FIG. 3(e) shows in three-dimensional view that the capping layer 313 and the precursor layer 311 are patterned to form a patterned precursor area 312 covered by the capping layer 313.

The patterned precursor area 312 may be a rectangular cuboid with an aspect ratio (x, y, z), or other shape such as a triangular shape, a square shape, and a polygon shape.

At block 207, the process 200 may include annealing the patterned precursor area with a coreactant, wherein the coreactant includes a group V element, and the patterned precursor area is transformed to a patterned epitaxial layer directly in contact with the surface of the substrate to be a channel area including an III-V compound formed by the precursor material and the coreactant. For example, as shown in FIG. 3(f), the process 200 may include annealing the patterned precursor area 312 with a coreactant. The coreactant may include a group V element, e.g., As. The patterned precursor area 312 may be transformed to a patterned epitaxial layer directly in contact with the surface of the substrate 301 to be a channel area 303. During the annealing process, the capping layer 313 may keep the patterned precursor area 312 and the channel area 303 in the desired shape formatted by the capping layer 313, e.g., a rectangular cuboid with an aspect ratio (x, y, z). The channel area 303 may include an III-V compound GaAs, formed by the precursor material Ga and the coreactant As. In some other embodiments, the III-V compound in the channel area 303 may be other binary III-V compound, a ternary III-V compound, or a quaternary III-V compound. FIG. 3(g) shows in three-dimensional view the formation of the channel area 303 may include an III-V compound GaAs. The channel area 303 is in direct contact with the surface of the substrate 301 without a buffer layer or another epitaxial layer in between. The annealing step may be carried out at a temperature in a range of from about 100° C. to about 500° C. In some embodiments, the precursor material 311 includes Ga, the capping layer 313 includes HfO₂, the coreactant includes AsH₃, and the III-V compound of the channel area 303 includes GaAs. Other elements of the group III elements or the group IV elements may be used as well.

At block 209, the process 200 may include removing the capping layer. At block 211, the process 200 may include forming a gate dielectric layer adjacent to the channel area and in direct contact with the channel area; and forming a gate electrode adjacent to the gate dielectric layer. For example, as shown in FIG. 3(h), the process 200 may include removing the capping layer 313, and forming a gate dielectric layer 305 above the channel area 303 and in direct contact with the channel area 303, and further forming a gate electrode 307 above the gate dielectric layer. In embodiments, the gate electrode 307, the gate dielectric layer 305, the channel area 303, and the substrate 301, may be similar to the gate electrode 107, the gate dielectric layer 105, the channel area 103, and the substrate 101, as shown in FIG. 1.

In addition, the process 200 may include forming a source area and a drain area above the substrate and adjacent to the channel area, forming a source electrode in contact with the source area, and forming a drain electrode in contact with the drain area, not shown.

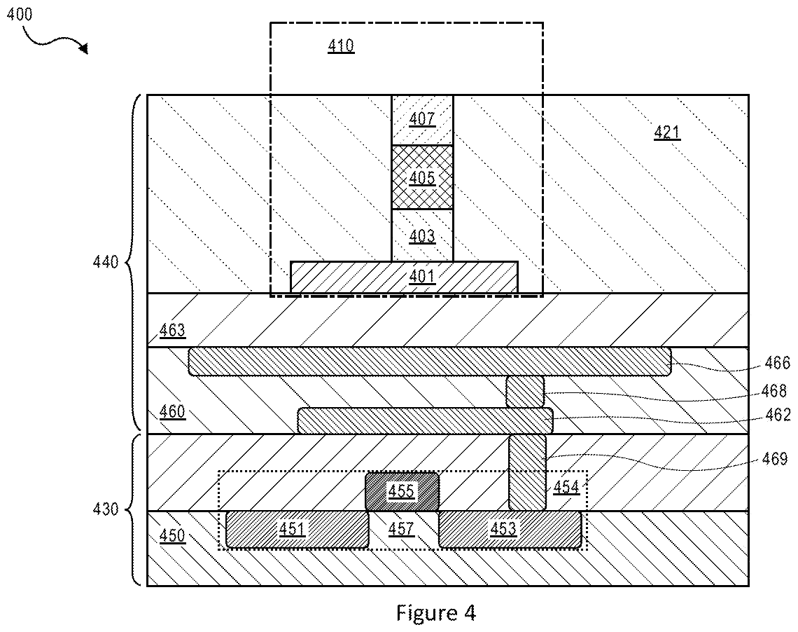

FIG. 4 schematically illustrates a diagram of a semiconductor device 400 including an III-V MOSFET 410 having an epitaxial layer with an III-V compound as a channel area 403 directly in contact with a surface of a substrate 401 formed in back-end-of-line (BEOL) 440 on a substrate 450, in accordance with some embodiments. The III-V MOSFET 410, the channel area 403, and the substrate 401 may be an example of the III-V MOSFET 100, the channel area 103, and the substrate 101 as shown in FIG. 1. Due to the low process temperature for the process 200, an III-V MOSFET, e.g., the III-V MOSFET 410, may be formed in an upper metal layer at the BEOL of a semiconductor device.

In embodiments, the III-V MOSFET 410 may be formed on the substrate 401, which is at the BEOL 440 of the semiconductor device 400. The III-V MOSFET 410 may include the substrate 401 with a substantially flat surface. The channel area 403 is above the substrate 401. The channel area 403 is an epitaxial layer including an III-V compound and directly in contact with the substrate 401. A gate dielectric layer 405 is above the channel area 403 and in direct contact with the channel area 403. A gate electrode 407 is above the gate dielectric layer 405. A source area and a drain area, not shown, may be above the substrate 401 and adjacent to the channel area 403. A source electrode may be in contact with the source area, and a drain electrode may be in contact with the drain area, not shown. The substrate 401, the channel area 403, the dielectric layer 405, the gate electrode 407 may all be embedded within an ILD layer 421.

In embodiments, the III-V MOSFET 410 may be formed at the BEOL 440. In addition to the III-V MOSFET 410, the BEOL 440 may further include a dielectric layer 460, and a dielectric layer 463, where one or more vias, e.g., a via 468, may be connected to one or more metal contacts, e.g., a metal contact 466 and a metal contact 462 within the dielectric layer 460. In embodiments, the metal contact 466 and the metal contact 462 may be of different metal layers at the BEOL 440.

In embodiments, the BEOL 440 may be formed on the FEOL 430. The FEOL 430 may include the substrate 450. In addition, the FEOL 430 may include other devices, e.g., a transistor 454. In embodiments, the transistor 454 may be a FEOL transistor, including a source 451, a drain 453, and a gate 455, with a channel 457 between the source 451 and the drain 453 under the gate 455. Furthermore, the transistor 454 may be coupled to interconnects, e.g., the metal contact 462, through a via 469.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

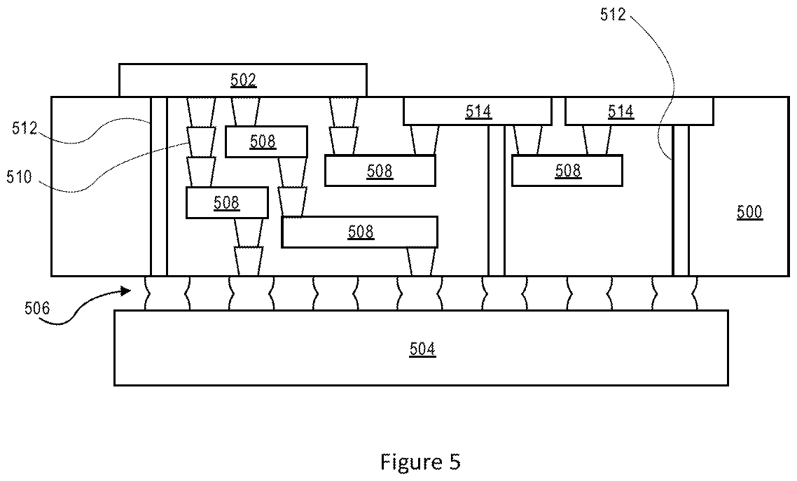

FIG. 5 illustrates an interposer 500 that includes one or more embodiments of the disclosure. The interposer 500 is an intervening substrate used to bridge a first substrate 502 to a second substrate 504. The first substrate 502 may be, for instance, a substrate support the III-V MOSFET 100 shown in FIG. 1, the III-V MOSFET 410 shown in FIG. 4, an III-V MOSFET formed by the process 200 shown in FIG. 2, or by the process 300 shown in FIG. 3. The second substrate 504 may be, for instance, a memory module, a computer motherboard, or another integrated circuit die. Generally, the purpose of an interposer 500 is to spread a connection to a wider pitch or to reroute a connection to a different connection. For example, an interposer 500 may couple an integrated circuit die to a ball grid array (BGA) 506 that can subsequently be coupled to the second substrate 504. In some embodiments, the first and second substrates 502/504 are attached to opposing sides of the interposer 500. In other embodiments, the first and second substrates 502/504 are attached to the same side of the interposer 500. And in further embodiments, three or more substrates are interconnected by way of the interposer 500.

The interposer 500 may be formed of an epoxy resin, a fiberglass-reinforced epoxy resin, a ceramic material, or a polymer material such as polyimide. In further implementations, the interposer may be formed of alternate rigid or flexible materials that may include the same materials described above for use in a semiconductor substrate, such as silicon, germanium, and other group III-V and group IV materials.

The interposer may include metal interconnects 508 and vias 510, including but not limited to through-silicon vias (TSVs) 512. The interposer 500 may further include embedded devices 514, including both passive and active devices. Such devices include, but are not limited to, capacitors, decoupling capacitors, resistors, inductors, fuses, diodes, transformers, sensors, and electrostatic discharge (ESD) devices. More complex devices such as radio-frequency (RF) devices, power amplifiers, power management devices, antennas, arrays, sensors, and MEMS devices may also be formed on the interposer 500.

In accordance with embodiments of the disclosure, apparatuses or processes disclosed herein may be used in the fabrication of interposer 500.

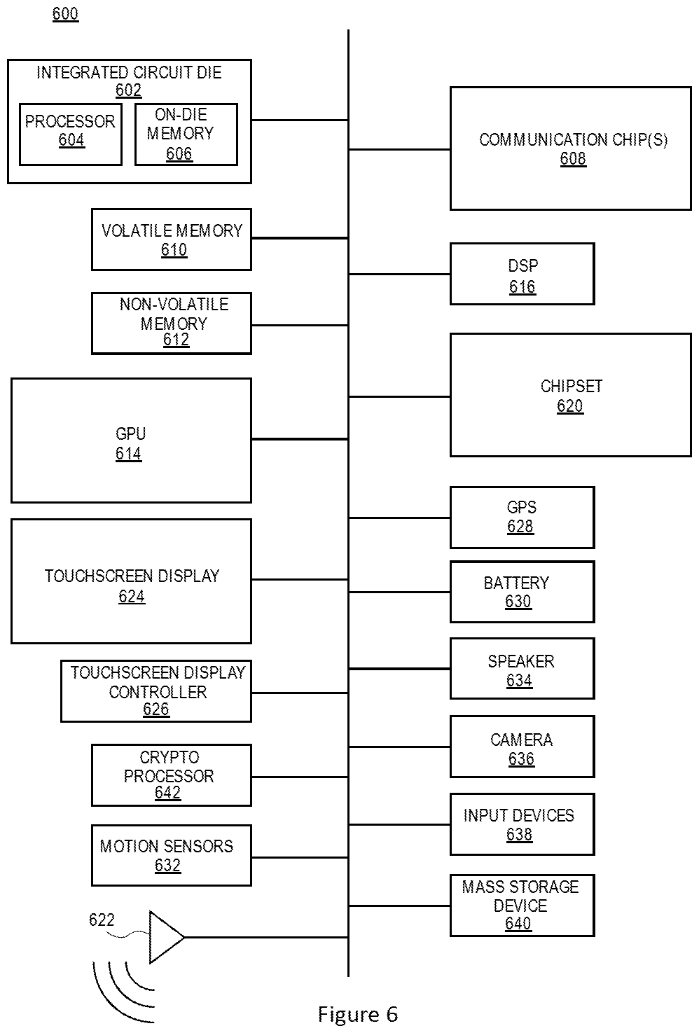

FIG. 6 illustrates a computing device 600 in accordance with one embodiment of the disclosure. The computing device 600 may include a number of components. In one embodiment, these components are attached to one or more motherboards. In an alternate embodiment, some or all of these components are fabricated onto a single system-on-a-chip (SoC) die, such as a SoC used for mobile devices. The components in the computing device 600 include, but are not limited to, an integrated circuit die 602 and at least one communications logic unit 608. In some implementations the communications logic unit 608 is fabricated within the integrated circuit die 602 while in other implementations the communications logic unit 608 is fabricated in a separate integrated circuit chip that may be bonded to a substrate or motherboard that is shared with or electronically coupled to the integrated circuit die 602. The integrated circuit die 602 may include a processor 604 as well as on-die memory 606, often used as cache memory, which can be provided by technologies such as embedded DRAM (eDRAM), or SRAM. For example, the processor 604 or the on-die memory 606, or other control circuits in the integrated circuit die 602 may include the III-V MOSFET 100 shown in FIG. 1, the III-V MOSFET 410 shown in FIG. 4, an III-V MOSFET formed by the process 200 shown in FIG. 2, or by the process 300 shown in FIG. 3.

In embodiments, the computing device 600 may include a display or a touchscreen display 624, and a touchscreen display controller 626. A display or the touchscreen display 624 may include a FPD, an AMOLED display, a TFT LCD, a micro light-emitting diode (μLED) display, or others.

Computing device 600 may include other components that may or may not be physically and electrically coupled to the motherboard or fabricated within a SoC die. These other components include, but are not limited to, volatile memory 610 (e.g., dynamic random access memory (DRAM), non-volatile memory 612 (e.g., ROM or flash memory), a graphics processing unit 614 (GPU), a digital signal processor (DSP) 616, a crypto processor 642 (e.g., a specialized processor that executes cryptographic algorithms within hardware), a chipset 620, at least one antenna 622 (in some implementations two or more antenna may be used), a battery 630 or other power source, a power electronic device 631, a voltage regulator (not shown), a global positioning system (GPS) device 628, a compass, a motion coprocessor or sensors 632 (that may include an accelerometer, a gyroscope, and a compass), a microphone (not shown), a speaker 634, a resonator 635, a camera 636, user input devices 638 (such as a keyboard, mouse, stylus, and touchpad), and a mass storage device 640 (such as hard disk drive, compact disk (CD), digital versatile disk (DVD), and so forth). In embodiments, various components may include the III-V MOSFET 100 shown in FIG. 1, the III-V MOSFET 410 shown in FIG. 4, an III-V MOSFET formed by the process 200 shown in FIG. 2, or by the process 300 shown in FIG. 3.

The computing device 600 may incorporate further transmission, telecommunication, or radio functionality not already described herein. In some implementations, the computing device 600 includes a radio that is used to communicate over a distance by modulating and radiating electromagnetic waves in air or space. In further implementations, the computing device 600 includes a transmitter and a receiver (or a transceiver) that is used to communicate over a distance by modulating and radiating electromagnetic waves in air or space.

The communications logic unit 608 enables wireless communications for the transfer of data to and from the computing device 600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communications logic unit 608 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Infrared (IR), Near Field Communication (NFC), Bluetooth, derivatives thereof, as well as any other wireless protocols that are designated as 3G, 4G, 5G, and beyond. The computing device 600 may include a plurality of communications logic units 608. For instance, a first communications logic unit 608 may be dedicated to shorter range wireless communications such as Wi-Fi, NFC, and Bluetooth and a second communications logic unit 608 may be dedicated to longer range wireless communications such as GPS, EDGE, GPRS, CDMA, WiMAX, LTE, Ev-DO, and others.

The processor 604 of the computing device 600 includes one or more devices, such as transistors. The term “processor” may refer to any device or portion of a device that processes electronic data from registers and/or memory to transform that electronic data into other electronic data that may be stored in registers and/or memory. The communications logic unit 608 may also include one or more devices, such as transistors.

In further embodiments, another component housed within the computing device 600 may contain one or more devices, such as the power electronic device 631, that are formed in accordance with implementations of the current disclosure, e.g., the III-V MOSFET 100 shown in FIG. 1, the III-V MOSFET 410 shown in FIG. 4, an III-V MOSFET formed by the process 200 shown in FIG. 2, or by the process 300 shown in FIG. 3.

In various embodiments, the computing device 600 may be a laptop computer, a netbook computer, a notebook computer, an ultrabook computer, a smartphone, a dumbphone, a tablet, a tablet/laptop hybrid, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 600 may be any other electronic device that processes data.

Some non-limiting Examples are provided below.

Example 1 may include a semiconductor device, comprising: a substrate with a surface that is substantially flat; a channel area above the substrate, wherein the channel area is an epitaxial layer directly in contact with the surface of the substrate, and the channel area includes an III-V compound; a gate dielectric layer adjacent to the channel area and in direct contact with the channel area; and a gate electrode adjacent to the gate dielectric layer.

Example 2 may include the semiconductor device of example 1 and/or some other examples herein, wherein the channel area is in direct contact with the surface of the substrate without a buffer layer or another epitaxial layer in between.

Example 3 may include the semiconductor device of example 1 and/or some other examples herein, further comprising: a source area and a drain area above the substrate and adjacent to the channel area; a source electrode in contact with the source area; and a drain electrode in contact with the drain area.

Example 4 may include the semiconductor device of example 1 and/or some other examples herein, further comprising: a spacer along a side wall of the gate electrode.

Example 5 may include the semiconductor device of example 1 and/or some other examples herein, wherein the III-V compound in the channel area includes a material selected from the group consisting of aluminum (Al), gallium (Ga), indium (In), nitrogen (N), phosphorus (P), arsenic (As), antimony (Sb), AlAs, GaAs, InₓGa₁₋ₓAs, InₓAl₁₋ₓAs InₓGa₁₋ₓP, InₓAl₁₋ₓP, GaAsₓSb₁₋ₓ, AlₓGa₁₋ₓAs_{y}P_{1-y} where x and y are between 0 and 1, InSb, InAs, AlP, GaP, InP, a binary III-V compound, a ternary III-V compound, and a quaternary III-V compound.

Example 6 may include the semiconductor device of example 1 and/or some other examples herein, wherein the channel area is of a shape selected from the group consisting of a rectangular cuboid, a triangular shape, a square shape, and a polygon shape.

Example 7 may include the semiconductor device of example 1 and/or some other examples herein, wherein the substrate includes a material selected from the group consisting of silicon, sapphire, SiC, GaN, AlN, SiO2, SiN, and Cu.

Example 8 may include the semiconductor device of example 1 and/or some other examples herein, wherein the substrate is a silicon substrate with a (111), (100), or (110) crystal plane as a principal plane.

Example 9 may include the semiconductor device of example 1 and/or some other examples herein, wherein the channel area includes a channel area selected from the group consisting of a FinFET channel, a vertical FET channel, a nanowire channel, a nanotube channel, and a nanoribbon channel.

Example 10 may include the semiconductor device of example 1 and/or some other examples herein, wherein the semiconductor device is an NMOS transistor, or a PMOS transistor.

Example 11 may include the semiconductor device of example 1 and/or some other examples herein, wherein the substrate is above a metal layer of back-end-of-the-line (BEOL) of the semiconductor device.

Example 12 may include a method for forming a semiconductor device, the method comprising: forming a precursor layer directly above and in contact with a surface of a substrate, wherein the precursor layer includes a precursor material with a group III element, and the surface of the substrate is substantially flat; forming a capping layer above the precursor layer; patterning the capping layer and the precursor layer to form a patterned precursor area covered by the capping layer, wherein the patterned precursor area is with an aspect ratio (x, y, z); annealing the patterned precursor area with a coreactant, wherein the coreactant includes a group V element, and the patterned precursor area is transformed to a patterned epitaxial layer directly in contact with the surface of the substrate to be a channel area including an III-V compound formed by the precursor material and the coreactant; removing the capping layer; forming a gate dielectric layer adjacent to the channel area and in direct contact with the channel area; and forming a gate electrode adjacent to the gate dielectric layer.

Example 13 may include the method of example 12 and/or some other examples herein, further comprising: forming a source area and a drain area above the substrate and adjacent to the channel area; forming a source electrode in contact with the source area; and forming a drain electrode in contact with the drain area.

Example 14 may include the method of example 12 and/or some other examples herein, wherein the annealing step is carried out at a temperature in a range of from about 100° C. to about 500° C.

Example 15 may include the method of example 12 and/or some other examples herein, wherein the channel area is in direct contact with the surface of the substrate without a buffer layer or another epitaxial layer in between.

Example 16 may include the method of example 12 and/or some other examples herein, wherein the III-V compound in the channel area includes a material selected from the group consisting of a binary III-V compound, a ternary III-V compound, and a quaternary III-V compound.

Example 17 may include the method of example 12 and/or some other examples herein, wherein a (x, y) aspect ratio of the channel area is 2:1.

Example 18 may include the method of example 12 and/or some other examples herein, wherein the substrate is above a metal layer of back-end-of-the-line (BEOL) of the semiconductor device.

Example 19 may include the method of example 12 and/or some other examples herein, wherein the capping layer includes a material selected from the group consisting of silicon oxide, silicon nitride, silicon oxynitride, silicon carbide, and a low-dielectric-constant (low-K) dielectric material.

Example 20 may include the method of example 12 and/or some other examples herein, wherein the capping layer has a thickness in a range from about 2 nm to about 500 nm.

Example 21 may include the method of example 12 and/or some other examples herein, wherein the precursor material includes Ga, the capping layer includes HfO₂, the coreactant includes AsH₃, and the III-V compound of the channel area includes GaAs.

Example 22 may include a computing device, comprising: a processor; and a memory device coupled to the processor, wherein the memory device or the processor includes a transistor comprising: a substrate with a surface that is substantially flat; a channel area above the substrate, wherein the channel area is an epitaxial layer directly in contact with the surface of the substrate, and the channel area includes an III-V compound; a gate dielectric layer adjacent to the channel area and in direct contact with the channel area; and a gate electrode adjacent to the gate dielectric layer.

Example 23 may include the computing device of example 22 and/or some other examples herein, further comprising: a source area and a drain area above the substrate and adjacent to the channel area; a source electrode in contact with the source area; and a drain electrode in contact with the drain area.

Example 24 may include the computing device of example 22 and/or some other examples herein, wherein the III-V compound in the channel area includes a material selected from the group consisting of a binary III-V compound, a ternary III-V compound, and a quaternary III-V compound.

Example 25 may include the computing device of example 22 and/or some other examples herein, wherein the computing device includes a device selected from the group consisting of wearable device or a mobile computing device, the wearable device or the mobile computing device including one or more of an antenna, a touchscreen controller, a battery, an audio codec, a video codec, a power amplifier, a global positioning system (GPS) device, a compass, a Geiger counter, an accelerometer, a gyroscope, a speaker, and a camera coupled with the processor.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated implementations, including what is described in the Abstract, is not intended to be exhaustive or to limit the embodiments of the present disclosure to the precise forms disclosed. While specific implementations and examples are described herein for illustrative purposes, various equivalent modifications are possible within the scope of the present disclosure, as those skilled in the relevant art will recognize.

These modifications may be made to embodiments of the present disclosure in light of the above detailed description. The terms used in the following claims should not be construed to limit various embodiments of the present disclosure to the specific implementations disclosed in the specification and the claims. Rather, the scope is to be determined entirely by the following claims, which are to be construed in accordance with established doctrines of claim interpretation.

What is claimed is:

1. A semiconductor device, comprising:
a substrate with a surface that is substantially flat;
a channel area above the substrate, wherein the channel area is an epitaxial layer directly in contact with the surface of the substrate, and the channel area includes an III-V compound;
a gate dielectric layer adjacent to the channel area and in direct contact with the channel area; and
a gate electrode adjacent to the gate dielectric layer.

2. The semiconductor device of claim 1, wherein the channel area is in direct contact with the surface of the substrate without a buffer layer or another epitaxial layer in between.

3. The semiconductor device of claim 1, further comprising:
a source area and a drain area above the substrate and adjacent to the channel area;
a source electrode in contact with the source area; and
a drain electrode in contact with the drain area.

4. The semiconductor device of claim 1, further comprising:
a spacer along a side wall of the gate electrode.

5. The semiconductor device of claim 1, wherein the III-V compound in the channel area includes a material selected from the group consisting of aluminum (Al), gallium (Ga), indium (In), nitrogen (N), phosphorus (P), arsenic (As), antimony (Sb), AlAs, GaAs, InₓGa₁₋ₓAs, InₓAl₁₋ₓAs InₓGa₁₋ₓP, InₓAl₁₋ₓP, GaAsₓSb₁₋ₓ, AlₓGa₁₋ₓAs_{y}P_{1-y} where x and y are between 0 and 1, InSb, InAs, AlP, GaP, InP, a binary III-V compound, a ternary III-V compound, and a quaternary III-V compound.

6. The semiconductor device of claim 1, wherein the channel area is of a shape selected from the group consisting of a rectangular cuboid, a triangular shape, a square shape, and a polygon shape.

7. The semiconductor device of claim 1, wherein the substrate includes a material selected from the group consisting of silicon, sapphire, SiC, GaN, AIN, SiO2, SiN and Cu.

8. The semiconductor device of claim 1, wherein the substrate is a silicon substrate with a (111), (100), or (110) crystal plane as a principal plane.

9. The semiconductor device of claim 1, wherein the channel area includes a channel area selected from the group consisting of a FinFET channel, a vertical FET channel, a nanowire channel, a nanotube channel, and a nanoribbon channel.

10. The semiconductor device of claim 1, wherein the semiconductor device is an NMOS transistor, or a PMOS transistor.

11. The semiconductor device of claim 1, wherein the substrate is above a metal layer of back-end-of-the-line (BEOL) of the semiconductor device.

12. A method for forming a semiconductor device, the method comprising:
forming a precursor layer directly above and in contact with a surface of a substrate, wherein the precursor layer includes a precursor material with a group III element, and the surface of the substrate is substantially flat;
forming a capping layer above the precursor layer;
patterning the capping layer and the precursor layer to form a patterned precursor area covered by the capping layer, wherein the patterned precursor area is with an aspect ratio (x, y, z);
annealing the patterned precursor area with a coreactant, wherein the coreactant includes a group V element, and the patterned precursor area is transformed to a patterned epitaxial layer directly in contact with the surface of the substrate to be a channel area including an III-V compound formed by the precursor material and the coreactant;
removing the capping layer;
forming a gate dielectric layer adjacent to the channel area and in direct contact with the channel area; and
forming a gate electrode adjacent to the gate dielectric layer.

13. The method of claim 12, further comprising:
forming a source area and a drain area above the substrate and adjacent to the channel area;
forming a source electrode in contact with the source area; and
forming a drain electrode in contact with the drain area.

14. The method of claim 12, wherein the annealing step is carried out at a temperature in a range of from about 100° C. to about 500° C.

15. The method of claim 12, wherein the channel area is in direct contact with the surface of the substrate without a buffer layer or another epitaxial layer in between.

16. The method of claim 12, wherein the III-V compound in the channel area includes a material selected from the group consisting of a binary III-V compound, a ternary III-V compound, and a quaternary III-V compound.

17. The method of claim 12, wherein a (x, y) aspect ratio of the channel area is 2:1.

18. The method of claim 12, wherein the substrate is above a metal layer of back-end-of-the-line (BEOL) of the semiconductor device.

19. The method of claim 12, wherein the capping layer includes a material selected from the group consisting of silicon oxide, silicon nitride, silicon oxynitride, silicon carbide, and a low-dielectric-constant (low-K) dielectric material.

20. The method of claim 12, wherein the capping layer has a thickness in a range from about 2 nm to about 500 nm.

21. The method of claim 12, wherein the precursor material includes Ga, the capping layer includes HfO₂, the coreactant includes AsH₃, and the III-V compound of the channel area includes GaAs.

22. A computing device, comprising:
a processor; and
a memory device coupled to the processor, wherein the memory device or the processor includes a transistor comprising:
a substrate with a surface that is substantially flat;
a channel area above the substrate, wherein the channel area is an epitaxial layer directly in contact with the surface of the substrate, and the channel area includes an III-V compound;
a gate dielectric layer adjacent to the channel area and in direct contact with the channel area; and
a gate electrode adjacent to the gate dielectric layer.

23. The computing device of claim 22, further comprising:
a source area and a drain area above the substrate and adjacent to the channel area;
a source electrode in contact with the source area; and
a drain electrode in contact with the drain area.

24. The computing device of claim 22, wherein the III-V compound in the channel area includes a material selected from the group consisting of a binary III-V compound, a ternary III-V compound, and a quaternary III-V compound.

25. The computing device of claim 22, wherein the computing device includes a device selected from the group consisting of wearable device or a mobile computing device, the wearable device or the mobile computing device including one or more of an antenna, a touchscreen controller, a battery, an audio codec, a video codec, a power amplifier, a global positioning system (GPS) device, a compass, a Geiger counter, an accelerometer, a gyroscope, a speaker, and a camera coupled with the processor.
